(19) United States
(12) Patent Application Publication
(10) Pub. No.: US 2025/0107421 A1
(43) Pub. Date: Mar. 27, 2025

(54) DISPLAY DEVICE

(71) Applicant: Samsung Display Co., LTD., Yongin-si (KR)

(72) Inventors: BOKWANG SONG, Yongin-si (KR); HYANG-A PARK, Yongin-si (KR); KWANG SOO BAE, Yongin-si (KR); DAE-YOUNG LEE, Yongin-si (KR); YOUNGMIN CHO, Yongin-si (KR); Soo Yeong Hong, Yongin-si (KR)

(21) Appl. No.: 18/883,965

(22) Filed: Sep. 12, 2024

(30) Foreign Application Priority Data
Sep. 27, 2023 (KR) 10-2023-0131113

(51) Int. Cl. H10K 59/88; H10K 39/34; H10K 59/131; H10K 59/38; H10K 59/40

(52) U.S. Cl. CPC H10K 59/88; H10K 39/34; H10K 59/131; H10K 59/38; H10K 59/40

(57) ABSTRACT

A display device includes a first pad group including first pads spaced apart in a first direction, a second pad group spaced apart from the first pad group in a second direction crossing the first direction, and including second pads spaced apart in the first direction, inspection lines between the first pads, extending in the second direction, spaced apart in the first direction, and respectively connected to the second pads, and a dummy pad between adjacent ones of the inspection lines.

### CROSS-REFERENCE TO RELATED APPLICATION(S)

The present application claims priority to, and the benefit of, Korean Patent Application No. 10-2023-0131113, filed on Sep. 27, 2023, in the Korean Intellectual Property Office, the entire disclosure of which is incorporated herein by reference.

### BACKGROUND

### 1. Field

Embodiments relate to a display device that is able to recognize biometric information.

### 2. Description of the Related Art

A display device includes a display area and a non-display area. A driving element (e.g., a transistor) and a light-emitting element (e.g., an organic light-emitting diode) that emits light by receiving a voltage or signal from the driving element are located in the display area of the display device, so that an image (e.g., predetermined image) may be displayed. An image is not displayed in the non-display area in which the light-emitting element is not located. A driving integrated circuit, a pad, or the like is located in the non-display area of the display device to provide a voltage or signal to the light-emitting element.

### SUMMARY

Embodiments provide a display device with improved reliability.

A display device according to one or more embodiments of the present disclosure includes a first pad group including first pads spaced apart in a first direction, a second pad group spaced apart from the first pad group in a second direction crossing the first direction, and including second pads spaced apart in the first direction, inspection lines between the first pads, extending in the second direction, spaced apart in the first direction, and respectively connected to the second pads, and a dummy pad between adjacent ones of the inspection lines.

The dummy pad may be spaced apart from the first pads in the first direction.

The inspection lines and the dummy pad may be alternately arranged.

A length of the first pads in the second direction may be substantially equal to a length of the dummy pad in the second direction.

The first pads and the dummy pad may include a same material.

A thickness of the first pads and the dummy pad may be greater than a thickness of the inspection lines.

The display device may further include a printed circuit board above the first pad group and the dummy pad.

The display device may further include an anisotropic conductive film between the first pad group and the printed circuit board.

The display device may further include an integrated circuit above the second pad group.

A display device according to one or more embodiments of the present disclosure includes a substrate including a display area, and a non-display area adjacent to the display area, a light-emitting element and a light-receiving element in the display area above the substrate, a first pad group in the non-display area above the substrate, and including first pads spaced apart in a first direction, inspection lines between the first pads, extending in a second direction crossing the first direction, and spaced apart in the first direction, and dummy pads respectively between adjacent ones of the inspection lines.

The dummy pads may be spaced apart from the first pads in the first direction.

The inspection lines and the dummy pads may be alternately arranged.

A length of the first pads in the second direction may be equal to a length of the dummy pads in the second direction.

The first pads and the dummy pads may include a same material.

A thickness of the first pads and the dummy pads may be greater than a thickness of the inspection lines.

The display device may further include a second pad group in the non-display area above the substrate, spaced apart from the first pad group in the second direction, and including second pads arranged in the first direction, wherein the inspection lines are respectively connected to the second pads.

The display device may further include a printed circuit board above the first pad group and the dummy pads, and an integrated circuit above the second pad group.

The second pads may be electrically connected to the light-receiving element.

The display device may further include a readout line above the substrate and electrically connected to the integrated circuit, wherein the second pads are electrically connected to the light-receiving element through the readout line.

The display device may further include an anisotropic conductive film between the first pad group and the printed circuit board.

In a display device according to embodiments of the present disclosure, the display device may include inspection lines located between pads electrically connected to a printed circuit board and dummy pads located between the inspection lines. Each of the pads and the dummy pads may have a thickness that is greater than that of the inspection lines. Because the dummy pads may compensate for a thickness difference between an area in which the pads are located and an area in which the inspection lines are located, the likelihood of associated problems, such as a pushing phenomenon of conductive particles included in an anisotropic conductive film that may occur during a bonding process of a display panel and the printed circuit board, may be reduced or prevented. Accordingly, damage to the display panel and the printed circuit board may be reduced or prevented, and the display device with improved reliability may be provided.

### BRIEF DESCRIPTION OF THE DRAWINGS

FIG. 1 is a plan view illustrating a display device according to one or more embodiments of the present disclosure.

FIG. 2 is an enlarged plan view of a portion of a display area of the display device of FIG. 1.

FIG. 3 is a cross-sectional view taken along the line I-I′ of FIG. 2.

FIG. 4 is an example of an enlarged plan view of area A of FIG. 1.

FIG. 5 is another example of an enlarged plan view of area A of FIG. 1.

FIG. 6 is a cross-sectional view taken along the line II-II′ of FIG. 4.

FIG. 7 is a cross-sectional view taken along the line III-III′ of FIG. 4.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

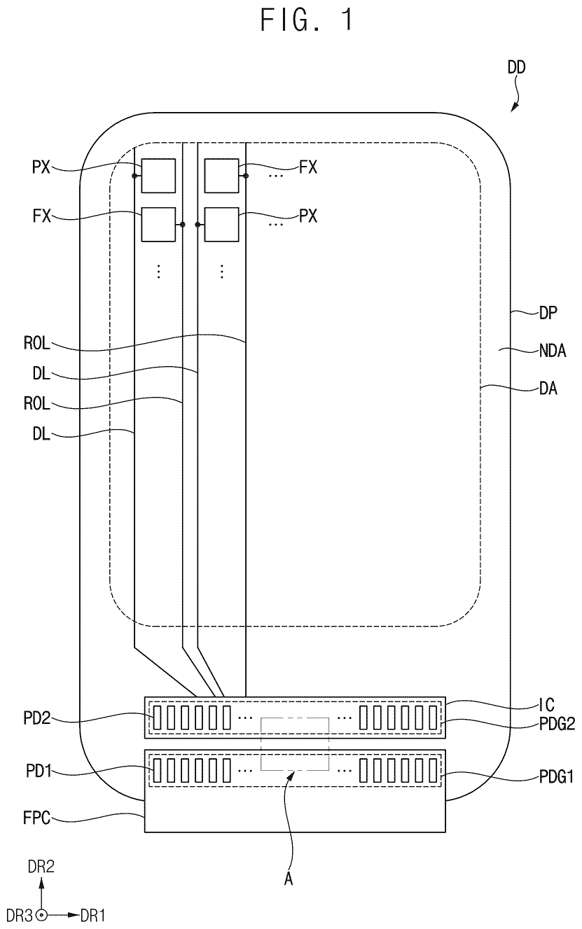

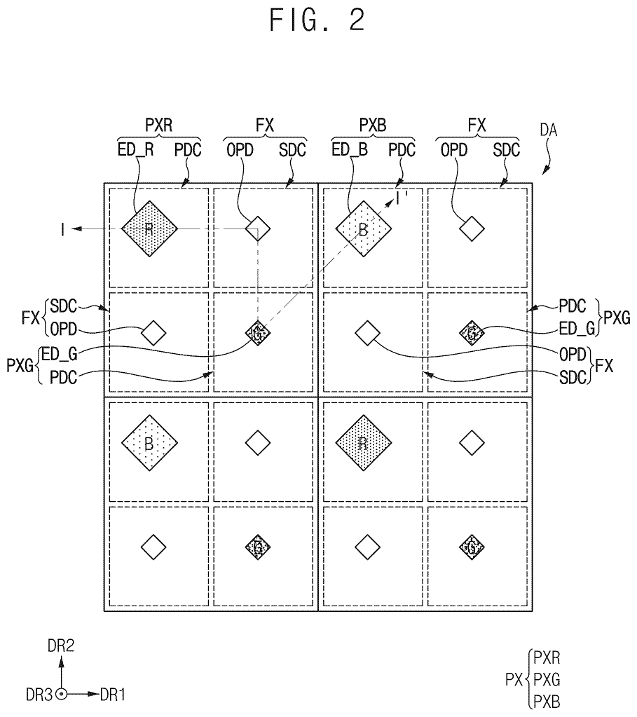

FIG. 1 is a plan view illustrating a display device according to one or more embodiments of the present disclosure. FIG. 2 is an enlarged plan view of a portion of a display area of the display device of FIG. 1.

Referring to FIGS. 1 and 2, a display device DD may include a display area DA and a non-display area NDA. In addition, the display device DD may include a display panel DP, an integrated circuit IC, and a printed circuit board FPC.

The display area DA may be an area that displays an image, and the non-display area NDA may be an area that does not display an image. The non-display area NDA may be located around the display area DA (e.g., in a plan view). For example, the non-display area NDA may entirely surround the display area DA.

The display panel DP may include pixels PX located in the display area DA and sensors FX located in the display area DA. In one or more embodiments, each of the sensors FX may be located between two pixels PX adjacent to each other in a plan view. The pixels PX and the sensors FX may be alternately arranged along a first direction DR1, and along a second direction DR2 intersecting or crossing the first direction DR1. For example, the first direction DR1 may be perpendicular to the second direction DR2.

Each of the pixels PX may emit light. As each of the pixels PX emits light, the display area DA may display an image. The pixels PX may include a first pixel PXR, a second pixel PXG, and a third pixel PXB that emit light in different wavelength bands. The first pixel PXR may emit a first light R, the second pixel PXG may emit a second light G, and the third pixel PXB may emit a third light B. The first, second, and third pixels PXR, PXG, and PXB may include a pixel-driving circuit PDC and first, second, and third light-emitting elements ED_R, ED_G, and ED_B that emit light in different wavelength bands, respectively.

In other words, the first pixel PXR may include the pixel-driving circuit PDC and the first light-emitting element ED_R that emits the first light R, the second pixel PXG may include the pixel-driving circuit PDC and the second light ED_G that emits the second light G, and the third pixel PXB may include the pixel-driving circuit PDC and the third light-emitting element ED_B that emits the third light B. For example, the first light-emitting element ED_R may emit the first light R in a red wavelength band, the second light-emitting element ED_G may emit the second light G in a green wavelength band, and the third light-emitting element ED_B may emit the third light B in a blue wavelength band, but the present disclosure is not limited thereto.

Each of the first, second, and third light-emitting elements ED_R, ED_G, and ED_B may be electrically connected to the pixel-driving circuit PDC. The pixel-driving circuit PDC may include at least one transistor and at least one capacitor.

Each of the sensors FX may include a sensor-driving circuit SDC and a light-receiving element OPD. The light-receiving element OPD may be an optical sensor that receives and recognizes light reflected by an external object. For example, the light-receiving element OPD may be an optical sensor that recognizes light in a visible light region reflected by an external object. In one or more embodiments, the light-receiving element OPD may be a biometric sensor that converts an optical signal into an electrical signal by recognizing light reflected from a user's body, such as a fingerprint, a vein, or the like.

The light-receiving element OPD may be electrically connected to the sensor-driving circuit SDC. The sensor-driving circuit SDC may include at least one transistor. In one or more embodiments, the sensor-driving circuit SDC and the pixel-driving circuit PDC may be concurrently or substantially simultaneously formed through the same process.

In one or more embodiments, the first pixel PXR and the third pixel PXB may be located in the same row and/or in the same column, and may be alternately arranged in the first direction DR1 and in the second direction DR2. The second pixel PXG may be located in different rows and different columns from the first pixel PXR and the third pixel PXB, and may be arranged in the first direction DR1 and the second direction DR2. In addition, the sensors FX may be located between the first pixel PXR and the third pixel PXB adjacent to each other, and may be located between two adjacent second pixels PXG. However, the present disclosure is not limited thereto, and the arrangement structure of the pixels PX and the sensors FX may be variously modified.

In one or more embodiments, the first light-emitting element ED_R may have an area that is larger than that of the second light-emitting element ED_G in a plan view. The third light-emitting element ED_B may have an area that is larger than or equal to that of the first light-emitting element ED_R in a plan view. In addition, the light-receiving element OPD may have an area that is smaller than that of both of the first light-emitting element ED_R and the third light-emitting element ED_B in a plan view. The light-receiving element OPD may have an area that is smaller than or equal to that of the second light-emitting element ED_G in a plan view. However, the present disclosure is not limited thereto, and the area of each of the first, second, and third light-emitting elements ED_R, ED_G, and ED_B and the light-receiving element OPD may be variously modified.

The display panel DP may further include data lines DL and readout lines ROL. The data lines DL and the readout lines ROL may extend in the second direction DR2, and may be spaced apart from each other in the first direction DR1. For example, the data lines DL and the readout lines ROL may be alternately located in the first direction DR1. The pixels PX may be electrically connected to the data lines DL, respectively, and the sensors FX may be electrically connected to the readout lines ROL, respectively.

The display panel DP may further include a first pad group PDG1 and a second pad group PDG2 located in the non-display area NDA. The second pad group PDG2 may be spaced apart from the first pad group PDG1 in the second direction DR2. The first pad group PDG1 may include first pads PD1 arranged in the first direction DR1, and the first pads PD1 may be spaced apart from each other in the first direction DR1. The second pad group PDG2 may include second pads PD2 arranged in the first direction DR1, and the second pads PD2 may be spaced apart from each other in the first direction DR1. The second pad group PDG2 may be electrically connected to the data lines DL and the readout lines ROL.

The integrated circuit IC may be located in the non-display area NDA. The integrated circuit IC may be located on the second pad group PDG2. The integrated circuit IC may be electrically connected to the display panel DP. The integrated circuit IC may be electrically connected to the data lines DL and the readout lines ROL through the second pad group PDG2. The integrated circuit IC may provide a signal or a voltage to the pixels PX and the sensors FX.

In one or more embodiments, the integrated circuit IC may include a data driver and a timing controller. For example, the integrated circuit IC may be a timing controller embedded data driver (TED) in which the data driver and the timing controller are implemented in a single integrated circuit. In addition, the integrated circuit IC may further include a readout circuit.

As the integrated circuit IC includes the data driver and the readout circuit, the integrated circuit IC may provide data signals to the pixels PX, and may receive sensing signals from the sensors FX. For example, the integrated circuit IC may provide the data signals to the pixels PX through the second pad group PDG2 and the data lines DL, and may receive the sensing signals from the sensors FX through the second pad group PDG2 and the readout lines ROL.

The printed circuit board FPC may be located in the non-display area NDA. The printed circuit board FPC may be located on the first pad group PDG1. The printed circuit board FPC may include driving circuits for driving the display device DD, a connector for power supply, or the like. The printed circuit board FPC may partially overlap the display panel DP. That is, a portion of the printed circuit board FPC may overlap the display panel DP, and another portion of the printed circuit board FPC may not overlap the display panel DP. The printed circuit board FPC may be electrically connected to the integrated circuit IC and the display panel DP.

The display device DD may sense an external input applied from outside. The external input may include various types of inputs provided from the outside of the display device DD. For example, the external input may include contact by a portion of a user's body, such as the user's hand or the like, as well as an external input (e.g., hovering) applied close to the display device DD or adjacent to the display device DD at a distance (e.g., predetermined distance). In addition, the external input may have various forms, such as force, pressure, temperature, light, or the like.

The display device DD may sense a user's biometric information applied from the outside. A biometric information sensing area that senses the user's biometric information may be provided in the display area DA of the display device DD. The biometric information sensing area may be provided in an entire area of the display area DA, or may be provided in a partial area of the display area DA.

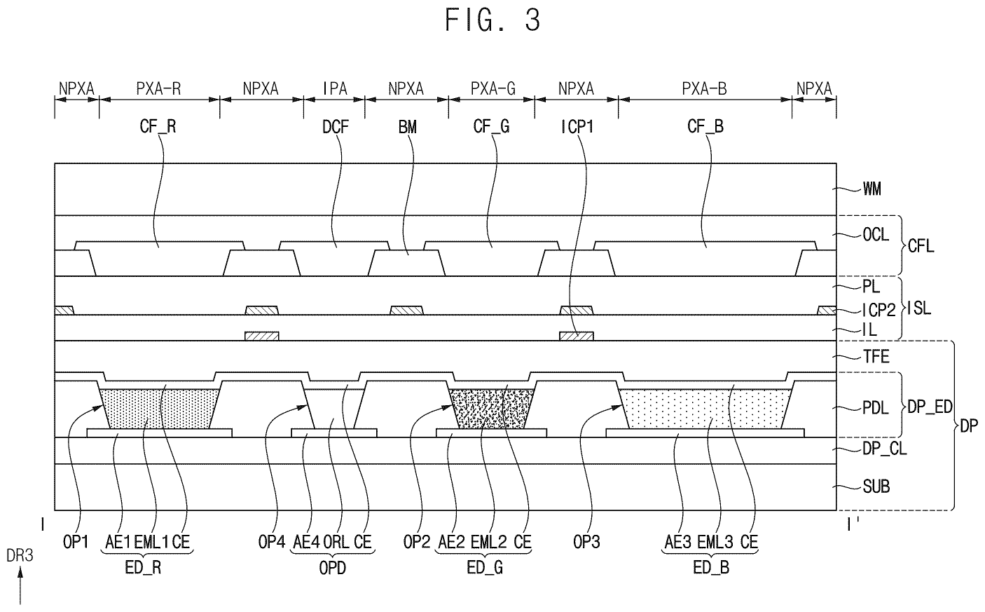

FIG. 3 is a cross-sectional view taken along the line I-I′ of FIG. 2.

Referring to FIGS. 1, 2, and 3, the display device DD may include the display panel DP, an input-sensing layer ISL, a color filter layer CFL, and a window WM.

The display panel DP may include a substrate SUB, a circuit layer DP_CL, an element layer DP_ED, and an encapsulation layer TFE.

The substrate SUB may include a transparent material or an opaque material. Examples of materials that may be used as the substrate SUB may include polyimide, quartz, glass, or the like. These may be used alone or in combination with each other.

The circuit layer DP_CL may be located on the substrate SUB. The circuit layer DP_CL may include an insulating layer, a semiconductor pattern, a conductive pattern, and a signal line. A preliminary insulating layer, a semiconductor layer, and a conductive layer may be formed on the substrate SUB through processes, such as coating, deposition, or the like, and the preliminary insulating layer, the semiconductor layer, and the conductive layer may be selectively patterned through a plurality of photolithography processes. Thereafter, the insulating layer, the semiconductor pattern, the conductive pattern, and the signal line included in the circuit layer DP-CL may be formed.

The element layer DP_ED may be located on the circuit layer DP_CL. The element layer DP_ED may include the first, second, and third light-emitting elements ED_R, ED_G, and ED_B and the light-receiving element OPD.

The element layer DP_ED may further include a pixel-defining layer PDL. The pixel-defining layer PDL may define first, second, and third openings OP1, OP2, and OP3 in which the first, second, and third light-emitting elements ED_R, ED_G, and ED_B are located, respectively, and a fourth opening OP4 in which the light-receiving element OPD is located. Accordingly, the first, second, and third light-emitting elements ED_R, ED_G, and ED_B and the light-receiving element OPD may be distinguished from each other based on the pixel-defining layer PDL.

The first light-emitting element ED_R may include a first pixel electrode AE1, a first light-emitting layer EML1, and a common electrode CE. The second light-emitting element ED_G may include a second pixel electrode AE2, a second light-emitting layer EML2, and the common electrode CE. The third light-emitting element ED_B may include a third pixel electrode AE3, a third light-emitting layer EML3, and the common electrode CE. The light-receiving element OPD may include a fourth pixel electrode AE4, a light-receiving layer ORL, and the common electrode CE.

The light-receiving element OLD may include the light-receiving layer ORL located between the fourth pixel electrode AE4 and the common electrode CE. The light-receiving layer ORL may include a light-receiving material that receives light, and that converts the light into an electrical signal. For example, the light-receiving layer ORL may include an organic material. In one or more embodiments, the light-receiving layer ORL may include an organic polymer material or the like as the light-receiving material. For example, the light-receiving layer ORL may include a conjugated polymer. The light-receiving layer ORL may include a thiophene-based conjugated polymer, a benzodithiophene-based conjugated polymer, a thieno[3,4-c]pyrrole-4,6-dion (TPD)-based conjugated polymer, a diketo-pyrrole-pyrrole (DPP)-based conjugated polymer, a benzothiazole (BT)-based conjugated polymer, or the like.

At least a portion of an upper surface of the first pixel electrode AE1 may be exposed by the first opening OP1, and at least a portion of an upper surface of the second pixel electrode AE2 may be exposed by the second opening OP2. At least a portion of an upper surface of the third pixel electrode AE3 may be exposed by the third opening OP3, and at least a portion of an upper surface of the fourth pixel electrode AE4 may be exposed by the fourth opening OP4.

First, second, and third light-emitting areas PXA-R, PXA-G, and PXA-B and a light-receiving area IPA may be respectively defined corresponding to areas of the first, second, third, and fourth pixel electrodes AE1, AE2, AE3, and AE4 respectively exposed by the first, second, third, and fourth openings OP1, OP2, OP3, and OP4. The first, second, and third light-emitting areas PXA-R, PXA-G, and PXA-B and the light-receiving area IPA may overlap the first, second, and third light-emitting elements ED_R, ED_G, and ED_B and the light-receiving element OPD, respectively.

A non-emitting area NPXA may be defined between the different areas PXA-R, PXA-G, PXA-B, and IPA. The non-emitting area NPXA may overlap the pixel-defining layer PDL in a plan view. The first, second, and third light-emitting areas PXA-R, PXA-G, and PXA-B and the light-receiving area IPA may be distinguished based on the non-emitting area NPXA.

The encapsulation layer TFE may be located on the element layer DP_ED. The encapsulation layer TFE may include at least one inorganic layer and at least one organic layer. For example, the encapsulation layer TFE may include a first inorganic layer, an organic layer, and a second inorganic layer sequentially stacked, but the present disclosure is not limited thereto.

The input-sensing layer ISL may be located on the encapsulation layer TFE. The input-sensing layer ISL may include a first conductive pattern ICP1, an insulating layer IL, a second conductive pattern ICP2, and a protective layer PL.

The first conductive pattern ICP1 may be located on the encapsulation layer TFE. The insulating layer IL may be located on the encapsulation layer TFE, and may cover the first conductive pattern ICP1. The second conductive pattern ICP2 may be located on the insulating layer IL.

The protective layer PL may be located on the insulating layer IL, and may cover the second conductive pattern ICP2. The protective layer PL may include an organic insulating material. The protective layer PL may protect the first and second conductive patterns ICP1 and ICP2 from moisture, oxygen, foreign substances, or the like.

Although FIG. 3 illustrates that the input-sensing layer ISL includes the first and second conductive patterns ICP1 and ICP2, the present disclosure is not limited thereto. For example, the input-sensing layer ISL may include only one of the first and second conductive patterns ICP1 and ICP2, or may further include a conductive pattern located on the second conductive pattern ICP2.

The color filter layer CFL may be located on the input-sensing layer ISL. The color filter layer CFL may include a first color filter CF_R, a second color filter CF_G, a third color filter CF_B, and a dummy color filter DCF.

The first color filter CF_R may overlap the first light-emitting element ED_R. That is, the first color filter CF_R may correspond to the first light-emitting area PXA-R. The first color filter CF_R may transmit the first light R, and may block light of a wavelength band different from that of the first light R.

The second color filter CF_G may overlap the second light-emitting element ED_G. That is, the second color filter CF_G may correspond to the second light-emitting area PXA-G. The second color filter CF_G may transmit the second light G, and may block light of a wavelength band different from that of the second light G.

The third color filter CF_B may overlap the third light-emitting element ED_B. That is, the third color filter CF_B may correspond to the third light-emitting area PXA-B. The third color filter CF_B may transmit the third light B, and may block light of a wavelength band different from that of the third light B.

In one or more embodiments, the dummy color filter DCF may overlap the light-receiving element OPD. That is, the dummy color filter DCF may correspond to the light-receiving area IPA. In one or more embodiments, the dummy color filter DCF may transmit one of the first, second, and third lights R, G, or B, and may block light of a wavelength band that is different therefrom. For example, the dummy color filter DCF may transmit the second light G, and may block light of a wavelength band that is different from that of the second light G, but the present disclosure is not limited thereto.

The color filter layer CFL may further include a black matrix BM. The black matrix BM may correspond to the non-emitting area NPXA. The black matrix BM may overlap the first and second conductive patterns ICP1 and ICP2.

The color filter layer CFL may further include an overcoating layer OCL. The overcoating layer OCL may include an organic insulating material. The overcoating layer OCL may compensate for a step difference between the first, second, and third color filters CF_R, CF_G, and CF_B. The overcoating layer OCL may have a thickness (e.g., predetermined thickness), and may planarize an upper surface of the color filter layer CFL. For example, the overcoating layer OCL may include an acrylate-based organic material.

The window WM may be located on the color filter layer CFL. The window WM may include an optically transparent material. For example, the window WM may include glass or plastic. The window WM may have a multilayer structure or a single layer structure. For example, the window WM may include a plurality of plastic films bonded by an adhesive, or may include a glass substrate and a plastic film bonded by an adhesive. The window WM may be bonded to the color filter layer CFL by an adhesive layer. The adhesive layer may include an optically clear adhesive, an optically clear adhesive resin, a pressure sensitive adhesive, or the like.

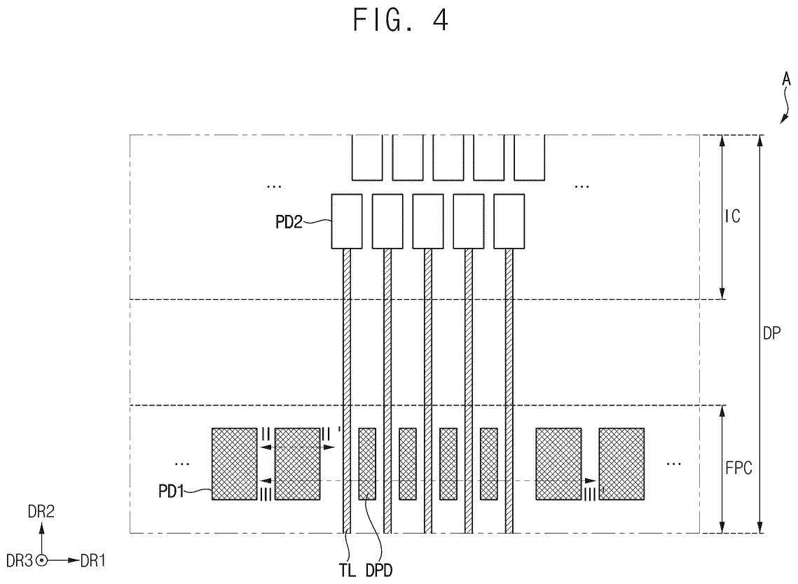

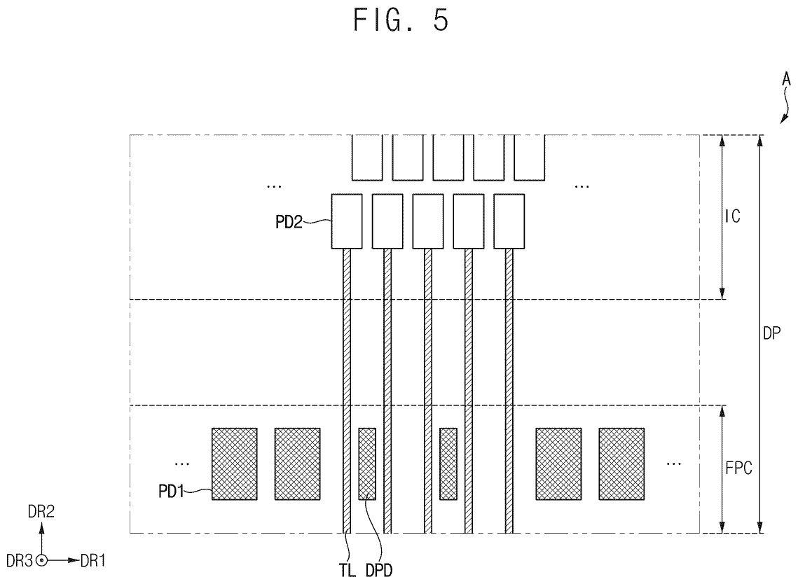

FIG. 4 is an example of an enlarged plan view of area A of FIG. 1. FIG. 5 is another example of an enlarged plan view of area A of FIG. 1.

Referring to FIGS. 1, 4, and 5, the display device DD may include the display panel DP, the integrated circuit IC, and the printed circuit board FPC.

The display panel DP may include the first pad group PDG1 and the second pad group PDG2 located in the non-display area NDA. The second pad group PDG2 may be spaced apart from the first pad group PDG1 in the second direction DR2. The first pad group PDG1 may include the first pads PD1 spaced apart from each other in the first direction DR1, and the second pad group PDG2 may include the second pads PD2 spaced apart from each other in the first direction DR1.

In one or more embodiments, the display panel DP may further include inspection lines TL and dummy pads DPD.

The inspection lines TL may be located between two first pads PD1 (e.g., two adjacent first pads PD1). The inspection lines TL may extend in the second direction DR2, and may be spaced apart from each other in the first direction DR1. The inspection lines TL may be respectively connected to the second pads PD2. The second pads PD2 connected to the inspection lines TLs may be electrically connected to the sensors FX through the readout lines ROL. For example, each of the inspection lines TL may include a metal, an alloy, a metal nitride, a conductive metal oxide, a transparent conductive material, or the like. These may be used alone or in combination with each other.

During a manufacturing process of the display device DD, the inspection lines TL may be connected to a multiplexer circuit that inspects driving of the sensors FX. That is, during the manufacturing process of the display device DD, one end of each of the inspection lines TL may be connected to the second pad PD2, and the other end of each of the inspection lines TL may be connected to the multiplexer circuit. Accordingly, there may be performed an inspection process of inspecting a driving of the sensors FX through the inspection lines TL. After the inspection process, a cutting process of laser-cutting a mother substrate into a plurality of cells may be performed. In this case, the mother substrate may be cut in a direction crossing the inspection lines TL, and the multiplexer circuit, and a portion of each of the inspection lines TL adjacent to the multiplexer circuit, may be removed. Accordingly, the display device DD, which does not include the multiplexer circuit, may be manufactured.

In one or more embodiments, the dummy pads DPD may be located between two inspection lines TL, respectively. The inspection lines TL and the dummy pads DPD may be alternately located along the first direction DR1.

For example, the display device DD may include n inspection lines TL and (n-1) dummy pads DPD (see FIG. 4). For another example, the display device DD may include n inspection lines TL and (n-2), or fewer, dummy pads DPD (see FIG. 5).

In addition, the dummy pads DPD may be arranged side by side with the first pads PD1 in the first direction DR1. The first pads PD1 and the dummy pads DPD may be arranged in the first direction DR1. That is, the printed circuit board FPC may be located on the first pad group PDG1 and the dummy pads DPD.

In one or more embodiments, a length of the dummy pads DPD in the second direction DR2 may be substantially equal to a length of the first pads PD1 in the second direction DR2. A width of the dummy pads DPD in the first direction DR1 may be less than a width of the first pads PD1 in the first direction DR1.

In one or more embodiments, the dummy pads DPD may include the same material as the first pads PD1, and may be formed through substantially the same process. In addition, the first pads PD1 and the dummy pads DPD may include the same material as the inspection lines TL, respectively. For example, each of the first pads PD1 and the dummy pads DPD may include a metal, an alloy, a metal nitride, a conductive metal oxide, a transparent conductive material, or the like. These may be used alone or in combination with each other.

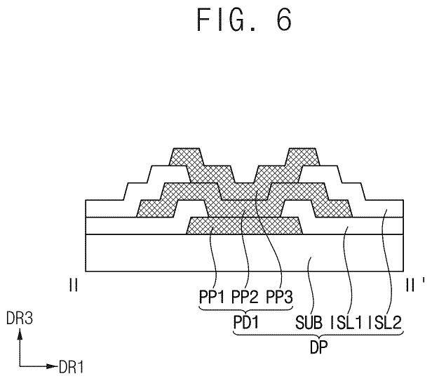

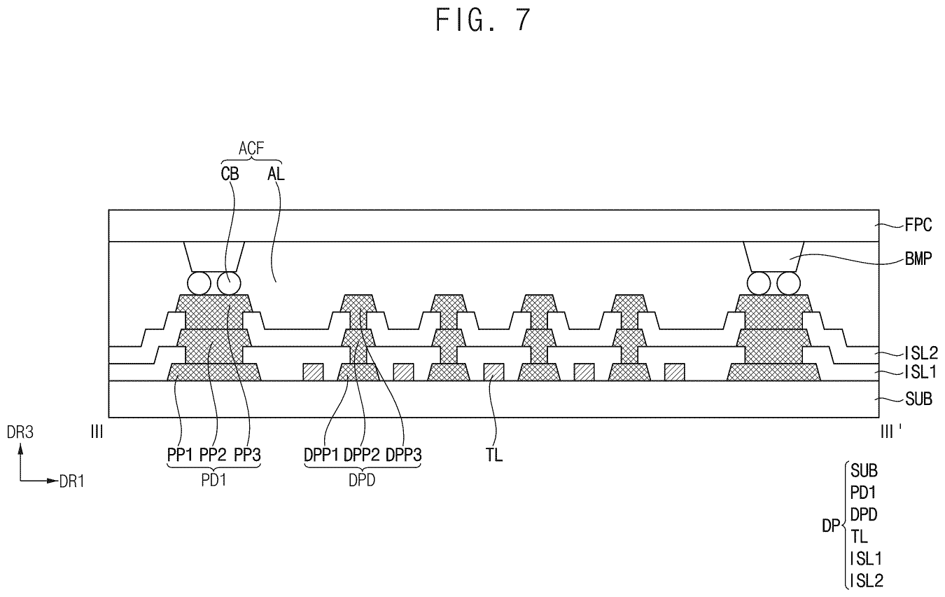

FIG. 6 is a cross-sectional view taken along the line II-II′ of FIG. 4. FIG. 7 is a cross-sectional view taken along the line III-III′ of FIG. 4. For example, FIG. 6 may be a cross-sectional view of the first pad PD1, and FIG. 7 may be a cross-sectional view of the first pads PD1, the dummy pads DPD, and the inspection lines TL.

Referring to FIGS. 4, 6, and 7, the display device DD may include the display panel DP, the printed circuit board FPC, and an anisotropic conductive film ACF.

The display panel DP may include the substrate SUB, the first pads PD1, the dummy pads DPD, the inspection lines TL, a first insulating layer ISL1, and a second insulating layer ISL2.

Each of the first pad PD1 and the dummy pad DPD may have a step

difference from the inspection line TL. In one or more embodiments, a thickness of each of the first pad PD1 and the dummy pad DPD may be greater than a thickness of the inspection line TL. In other words, a thickness of each of the first pad PD1 and the dummy pad DPD in a third direction DR3, which crosses each of the first direction DR1 and the second direction DR2, may be greater than a thickness of the inspection line TL in the third direction DR3. For example, the third direction DR3 may be perpendicular to each of the first direction DR1 and second directions DR1 and DR2.

Each of the first pad PD1 and the dummy pad DPD may have a multilayer structure. For example, the first pad PD1 may include a first pad pattern PP1, a second pad pattern PP2, and a third pad pattern PP3. The dummy pad DPD may include a first dummy pad pattern DPP1, a second dummy pad pattern DPP2, and a third dummy pad pattern DPP3. The inspection line TL may have a single layer structure.

The first pad patterns PP1, the first dummy pad patterns DPP1, and the inspection lines TL may be located on the substrate SUB.

The first insulating layer ISL1 may be located on the first pad patterns PP1, the first dummy pad patterns DPP1, and the inspection lines TL. The first insulating layer ISL1 may define openings respectively exposing at least a portion of an upper surface of the first pad pattern PP1 and at least a portion of an upper surface of the first dummy pad pattern DPP1. The first insulating layer ISL1 may cover the inspection lines TL.

The second pad patterns PP2 and the second dummy pad patterns DPP2 may be respectively located on the first pad patterns PP1 and the first dummy pad patterns DPP1. The second pad pattern PP2 and the second dummy pad pattern DPP2 may be respectively in contact with the first pad pattern PP1 and the first dummy pad pattern DPP1 through respective openings.

The second insulating layer ISL2 may be located on the first insulating layer ISL1, the second pad patterns PP2, and the second dummy pad patterns DPP2. The second insulating layer ISL2 may define openings respectively exposing at least a portion of an upper surface of the second pad pattern PP2 and an upper surface of the second dummy pad pattern DPP2.

The third pad patterns PP3 and the third dummy pad patterns DPP3 may be respectively located on the second pad pattern PP2 and the second dummy pad patterns DPP2. The third pad pattern PP3 and the third dummy pad pattern DPP3 may be respectively in contact with the second pad pattern PP2 and the second dummy pad pattern DPP2 through respective openings.

The first insulating layer ISL1 and the second insulating layer ISL2 may correspond to the insulating layer included in the circuit layer DP_CL. In addition, the first, second, and third pad patterns PP1, PP2, and PP3 may include the same material as the conductive pattern included in the circuit layer DP_CL, and may be formed through the same process.

Although FIGS. 6 and 7 illustrate that each of the first pad PD1 and the dummy pad DPD have a three-layered structure, the present disclosure is not limited thereto. For example, each of the first pad PD1 and the dummy pad DPD may have a structure of two or fewer layers, or of four or more layers.

The printed circuit board FPC may be located on/above the first pad PD1 and the dummy pad DPD. The printed circuit board FPC may include a bump BMP. The bump BMP may overlap the first pad PD1 in a plan view. The bump BMP may include a conductive material. The bump BMP may be electrically connected to the first pad PD1. The printed circuit board FPC may output a voltage, a signal, or the like to the display panel DP through the bump BMP.

The anisotropic conductive film ACF may be located between the display panel DP and the printed circuit board FPC. For example, the anisotropic conductive film ACF may be located between the first pads PD1 and the dummy pads DPD, and the printed circuit board FPC. The anisotropic conductive film ACF may bond the first pad PD1 and the bump BMP. The first pad PD1 and the bump BMP may be electrically connected through the anisotropic conductive film ACF. Accordingly, the anisotropic conductive film ACF may electrically connect the display panel DP and the printed circuit board FPC. The anisotropic conductive film ACF may include an adhesive layer AL and conductive particles CB arranged in the adhesive layer AL.

The adhesive layer AL may include an insulating polymer material. Examples of the insulating polymer material that may be used as the adhesive layer AL may include epoxy resin, acrylic resin, phenol resin, melamine resin, diallyl phthalate resin, urea resin, polyimide resin, polystyrene resin, polyurethane resin, polyethylene resin, polyvinyl acetate resin, or the like. These may be used alone or in combination with each other.

The conductive particles CB may be located between the first pad PD1 and the bump BMP. Accordingly, the conductive particles CB may electrically connect the display panel DP and the printed circuit board FPC. In one or more embodiments, each of the conductive particles CB may include a core including an insulating polymer material and a conductive film surrounding the core and including a conductive metal material.

To electrically connect the display panel DP and the printed circuit board FPC through the anisotropic conductive film ACF, a bonding process of applying heat and pressure may be performed. Through the bonding process, the anisotropic conductive film ACF may bond the first pad PD1 and the bump BMP.

In this case, if the conductive particles CB are not fixed and pushed by the applied heat and pressure, a connection failure may occur between the first pad PD1 and the bump BMP. For example, as the thickness of the first pads PD1 is greater than the thickness of the inspection lines TL, if a relatively large step difference is formed between an area in which the first pads PD1 are located and an area in which the inspection lines TL are located, the conductive particles CB may be concentrated toward the area in which the inspection lines TL are located. Accordingly, problems, such as dark spots, electrical shorts, and/or damage to the first pad PD1 or the bump BMP, may occur.

On the contrary, even if the thickness of the first pads PD1 is greater than the thickness of the inspection lines TL, if a relatively small step difference is formed between the area in which the first pads PD1 are located and the area in which the inspection lines TL are located, concentration of the conductive particles CB toward the area in which the inspection lines TL are located may be reduced or prevented.

The display device DD according to one or more embodiments of the present disclosure may include the inspection lines TL located between the first pads PD1 and the dummy pads DPD located between the inspection lines TL. Each of the first pads PD1 and the dummy pads DPD may have the thickness greater than that of the inspection lines TL. Because the dummy pads DPD may compensate for the thickness difference between the area in which the first pads PD1 are located and the area in which the inspection lines TL are located, problems, such as a pushing phenomenon of the conductive particles CB, which may occur during the bonding process of the display panel DP and the printed circuit board FPC, may be reduced or prevented. Accordingly, damage to the display panel DP and the printed circuit board FPC may be reduced or prevented, and the display device DD with improved reliability may be provided.

The present disclosure can be applied to various display devices. For example, the present disclosure is applicable to various display devices, such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a first pad group comprising first pads spaced apart in a first direction;
a second pad group spaced apart from the first pad group in a second direction crossing the first direction, and comprising second pads spaced apart in the first direction;
inspection lines between the first pads, extending in the second direction, spaced apart in the first direction, and respectively connected to the second pads; and
a dummy pad between adjacent ones of the inspection lines.

2. The display device of claim 1, wherein the dummy pad is spaced apart from the first pads in the first direction.

3. The display device of claim 1, wherein the inspection lines and the dummy pad are alternately arranged.

4. The display device of claim 1, wherein a length of the first pads in the second direction is substantially equal to a length of the dummy pad in the second direction.

5. The display device of claim 1, wherein the first pads and the dummy pad comprise a same material.

6. The display device of claim 1, wherein a thickness of the first pads and the dummy pad is greater than a thickness of the inspection lines.

7. The display device of claim 1, further comprising a printed circuit board above the first pad group and the dummy pad.

8. The display device of claim 7, further comprising an anisotropic conductive film between the first pad group and the printed circuit board.

9. The display device of claim 1, further comprising an integrated circuit above the second pad group.

10. A display device comprising:
a substrate comprising a display area, and a non-display area adjacent to the display area;
a light-emitting element and a light-receiving element in the display area above the substrate;
a first pad group in the non-display area above the substrate, and comprising first pads spaced apart in a first direction;
inspection lines between the first pads, extending in a second direction crossing the first direction, and spaced apart in the first direction; and
dummy pads respectively between adjacent ones of the inspection lines.

11. The display device of claim 10, wherein the dummy pads are spaced apart from the first pads in the first direction.

12. The display device of claim 10, wherein the inspection lines and the dummy pads are alternately arranged.

13. The display device of claim 10, wherein a length of the first pads in the second direction is equal to a length of the dummy pads in the second direction.

14. The display device of claim 10, wherein the first pads and the dummy pads comprise a same material.

15. The display device of claim 10, wherein a thickness of the first pads and the dummy pads is greater than a thickness of the inspection lines.

16. The display device of claim 10, further comprising a second pad group in the non-display area above the substrate, spaced apart from the first pad group in the second direction, and comprising second pads arranged in the first direction,
wherein the inspection lines are respectively connected to the second pads.

17. The display device of claim 16, further comprising:
a printed circuit board above the first pad group and the dummy pads; and
an integrated circuit above the second pad group.

18. The display device of claim 17, wherein the second pads are electrically connected to the light-receiving element.

19. The display device of claim 18, further comprising a readout line above the substrate and electrically connected to the integrated circuit,
wherein the second pads are electrically connected to the light-receiving element through the readout line.

20. The display device of claim 17, further comprising an anisotropic conductive film between the first pad group and the printed circuit board.
